(19) United States
(12) Patent Application Publication
(10) Pub. No.: US 2013/0305606 A1
(43) Pub. Date: Nov. 21, 2013

(54) Smart Container for Monitoring a Growing Plant and Method of Making It

(71) Applicant: Johnathan Everrett Lonsdale, Lake Placid, FL (US)

(72) Inventor: Johnathan Everrett Lonsdale, Lake Placid, FL (US)

(21) Appl. No.: 13/475,939

(22) Filed: May 18, 2012

(51) Int. Cl. A01G 9/02; H05K 13/00; F21V 33/00

(52) U.S. Cl. 47/66.6; 29/592.1

(57) ABSTRACT

A container (and method of making it) for sensing and displaying the growing condition of a growing plant in a medium (such as soil) including a first indicator (preferably a colored indicator) that the growing medium is too moist, a second indicator (preferably of a different color) indicating that the growing medium is too dry and an optional indicator regarding the condition of a power supply which powers the sensing and indicating. The indicating circuits are designed for a longer useful life.

### BACKGROUND OF THE INVENTION

1. Field of the Invention

The present invention is an improved container for monitoring one or more growing plants and method of making it, wherein the container includes a sensor sensing at least one growing condition (e.g., moisture content of the soil) and providing a visible display of the condition, as well as an optional indicator of the condition of its power supply.

2. Background Art

In growing plants in a nursery, retail outlet or other environment, it is well known that the growing conditions determine whether a plant will grow and whether it will grow at the desired rate. Monitoring at least one growing condition and influencing the environment for that growing condition can improve the chances of successful growth and the rate at which the plant grows.

One of the more important characteristics of the growing environment is the level of moisture in the soil (or other growing environment). If the level of moisture in the growing environment is too high, then the plants tend to rot. If the level of moisture in the growing environment is too low, then the plant does not grow well (and may even die) from an inadequate amount of moisture.

Various types of systems are known for watering plants in a growing environment, but many of these systems tend to water a large number of plants simultaneously, with some such systems having little control over how much water each plant receives. Since each plant depends on the proper amount of moisture being applied to it, it is desirable that an indicator monitor the growing conditions of each plant in its own pot.

Of course, monitoring each pot can become expensive and time consuming. An operator can determine the growing condition of each plant in its pot, either visibly, manually or through use of a hand-held device or a condition indicating stake in the pot, but any of these methods is a slow and labor intensive process and often depends on the worker correctly sensing the condition or reading a stake (perhaps its color) which has to be properly positioned within the soil to have an accurate reading.

Some of the moisture sensing systems of the prior art are slow to respond to moisture (or the lack of moisture) and some are dependent on the location of a sensor—that is, if the sensor is in a pool of water, the reading may appear to be adequate, but if the moisture is localized in the area of the sensor and not distributed through the soil, the plant may lack adequate moisture.

Further, some of the systems are difficult to determine the condition (for example, amount of moisture) of a pot or collection of pots. if each pot includes a readout device which has numbers or words displayed, a worker may have to position himself in close proximity to each pot in order to determine whether it needs water or not. Also, if the indicator is located on one side of the pot, care must be taken to orient the pot in an orientation for viewing (in the right direction and at the right height) in order to quickly and easily read the moisture sensor.

The prior art lacks a system for quickly easily and without doubt determine a growing condition of the plant in the pot (such as whether the plants need water), to sort the pots that need changing (those that need water from those that have too much water) and to separate the pots needing a change (needing water) from those which do not (have too much water).

Further, it would be desirable to have an indicator in the pots that responds to the watering and quickly provides a signal that the plant has been adequately watered.

Automatic monitoring systems have also been proposed in the art, but these systems are sometimes complex and often involve using an electrical system which requires a significant amount of power. If such systems are battery operated, determining the condition of the batteries and changing batteries can also become time consuming and expensive, and if a battery fails, the lack of indication can allow for failure of the entire monitoring system.

Accordingly, the condition monitoring systems of the prior art have significant disadvantages and limitations.

### SUMMARY OF THE INVENTION

The present invention overcomes the disadvantages and limitations of the prior art systems by providing an easily perceived optical signal indicating at least one growing condition of the growing medium in a pot.

In one embodiment of the present invention, an outer pot with a translucent portion includes circuitry and multiple, different-colored lamps or LEDs which are powered by a power supply to provide a colored indication of at least one growing condition of the plant and pot. An inner pot includes the plant, growing medium containing the water and a sensor (sensing rods located at a spaced interval). The sensing rods extend through seals in the inner pot into the outer pot with a translucent portion where circuitry, indicators (such as colored indicating lamps) and a power supply are located, but protected from the soil and water in the inner pot by, inter alia, the seals.

For example, in one embodiment of the present invention, the indicating lamps or lights include a first LED giving off a first colored light when energized to indicate an inadequate amount of moisture in the soil and a second LED giving off a second colored light when energized to indicate an excessive amount of water in the soil. The LEDs are mounted within the outer pot near its center to provide a glow through the translucent portion, potentially outwardly from the pot in all directions around the circumference of the pot. The LED emitting light through the translucent portion of the outer pot provides a glow of a color which can be identified from afar and recognized quickly and easily. The glow (or lack of glow) from each pot can allow a single operator to monitor quickly and easily a large number of pots at substantially the same time by looking for pots which are glowing (or not glowing) and taking the appropriate steps to ameliorate the growing conditions.

The present invention also recognizes that the monitoring system may be dependent on the power supply and providing an indication when the power supply is weak or failing. That is, if the system has a power supply in the form of batteries and the batteries are near the end of their life, those batteries are not reliable and may soon fail to properly provide a signal of the growing condition being monitored. It is desirable, although optional, to provide a signal that indicates the condition of the power supply, a signal which either confirms the existence of adequate power or indicates that adequate power is not present. The present invention includes an optional indicator regarding the power of the power supply. In one embodiment, as the power of the power supply diminishes and goes below a threshold, one of the LEDs is flashed periodically to provide a indicator (indicating that the power supply need to be replaced or the circuit will fail soon), preferably an indicator which itself does not require much power. When the power supply is weak, then the signals can indicate that the power supply needs to be replaced or that the future lack of indicator may not be reliable (when the power supply is too weak to illuminate the LEDs, the system will no longer function in its intended role.)

The sensor of the preset invention may be coupled to one or more external monitors or warning systems or recording devices of other types if desired. For example, a wireless communication system such as Bluetooth or RFID could be used to send a signal from a pot (or from a plurality of identifiable pots) to a remote monitoring system of an undesirable condition (such as too much water, too little water or a low power supply). Alternatively, the pots could be hard wired to a data collection system such as a computer or other recording device which keeps track of the status of the pots and provides an output indicative of which pots need watering, as desired.

The present invention may include circuitry to extend the life of the power supply, as intermittently energizing the LED in a pulsing mode, for example, and the monitoring of the growing conditions may be done periodically (even x minutes) rather than continuously (every cycle of the data processing system).

Other objects and advantages of the present invention will be apparent to one of skill in the art in view of the following description of the invention.

### BRIEF DESCRIPTION OF THE DRAWINGS

FIG. 1 is a cross-sectional view of a pot assembly useful in one embodiment of the present invention;

FIG. 2 is a logical diagram showing the logic accomplished in one embodiment of the present invention;

FIG. 3 is a schematic diagram of the logic for one sensing circuit for the growing condition of the present invention;

FIG. 4 is a schematic diagram of the logic for sensing the power supply in the present invention; and

FIG. 5 is a perspective view of a plurality of pots of the present invention.

### DETAIL DESCRIPTION OF THE PREFERRED EMBODIMENT

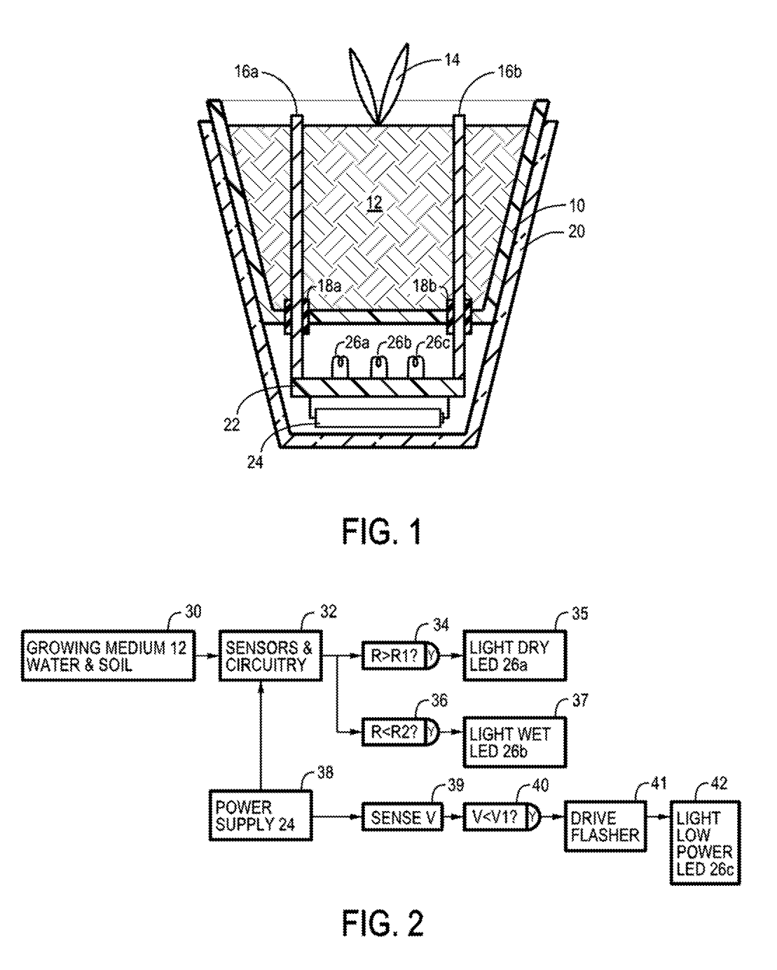

FIG. 1 is a view of a system for monitoring the moisture content of a plant incorporating and illustrating the principles of the present invention. A first container 10 includes a growing medium 12 and a plant 14 with a first sensing rod 16a and a second sensing rod 16b located within the first container and with the growing medium 12 extending between the sensing rods 16a, 16b. The growing medium 12 is a type of dirt (such as interior potting soil) which is available commercially under a variety of brands, in its preferred embodiment, although the present invention is suited to hydroponic and other growing mediums, as desired. The growing medium 12 typically includes an unknown and variable amount of moisture content, an amount which changes as the plant uses water and as the container is periodically watered from an external source such as a hose or drip irrigation system. Ideally, the water provided to the first container has known qualities, such as tap water with typically minerals and ions which conduct electrical currents to some degree (and not distilled or de-ionized water, which is a rather poor conductor of electrical current), and typically the growing medium has characteristics such as conductivity which is within a limited range, and the addition of water increases the conductivity of the soil in a generally-known manner. The first container 10 may be a typical growing container, which may be made of plastic, metal or even a coated cardboard as desired, of the type generally used in a nursery, retail store or other environment prior to planting.

A second container 20 is mounted proximate to the first container 10 and provides a separate chamber for the monitoring and indicating portions of the present invention. Portions of the first sensing rod 16a and the second sensing rod 16b extend through apertures in a surface of the first container 10 and into the second container 20. Since the monitoring and indicating portions of the present invention may be subject to adverse effects from soil and/or water from the first container, it is desirable to isolate the second chamber and its circuitry from the adverse effects of the soil and/or water by providing a first seal 18a and a second seal 18b where the rods 16a, 16b extend through the first container. The seals 18a, 18b are preferably a silicone material (although epoxy may be used to advantage in some applications) and provide deterrence to the soil or water from the first container 10 entering into the second container 20. Alternatively, connections of the sensing and indicating devices in the second container 20 could be isolated from the dirt and water in other ways, such as potting the components in a separate region or package, insulating the connections or positioning the components away from the lower portions of the container.

The second container 20 is made from a material which allows at least some light to be transmitted therethrough, such as a translucent plastic. One such plastic is acrylic and another such plastic is the plastic of which milk jugs are made (believed to be polyethylene), although other plastics of suitable thicknesses are known to provide translucent (or even transparent) qualities which are desirable in the present invention.

The sensing rods 16a, 16b are positioned generally vertical and generally parallel to each other and spaced approximately a preset distance to provide a uniform amount of growing medium between the sensing rods 16a, 16b. In one embodiment, the rods are made of steel and are placed approximately 1 inch apart and extending through the growing environment. In this instance, using indoor potting soil as the growing medium and tap water with the normal minerals and ions, it has been found that a resistance of approximately 200 ohms indicates that the soil is too moist and a resistance of approximately 800 ohms indicates that the soil is too dry. By suitable circuitry, the circuitry attached to the sensors can be established which provides triggering signals at the desired thresholds (and may be adjusted for variations in the type of rods, the spacing of the rods, the type of soil and/or the type of moisture being provided.

The indicators 26a, 26b, 26c are light emitting diodes (LEDs) of different colors in the preferred embodiment, although other sources of light can be used, with filters or other modifications if desired. That is, if LEDs having different colors are not conveniently available, LEDs having a single color can be used, with a piece of colored material covering at least one LED to provide different color coming from the other LED. That is, a pair of white light LEDs could be used, with one covered with a red transmitting covering on one and a blue transmitting covering on the other to provide two LEDs which seem to emit different colored light.

As the light from an LED is transmitted through the translucent container, it provides a glowing appearance which draws little power yet provides an immediately-apparent signal that the indicator has been energized. Placing the LED toward the center of the second container 20 and keeping a generally-clear path to the periphery of the container will allow a single LED to provide a signal all around the periphery of the container 20. Of course, a second LED is a small obstruction in the light path and would not significantly impact the ability of a single LED to provide a signal when illuminated substantially all around the second container 20, allowing for the container to be placed in any orientation and the observer to be in any position with respect to the container and still observe the indication when the LED is illuminated.

The power supply 24 is a source of current at approximately 3 volts in its preferred embodiment, a voltage which may be provided by a pair of AA batteries or by other suitable batteries.

The second container 20 surrounds, at least partially, the first and second sensor rods 16a, 16b and includes circuitry 22, a power supply 24 and a first indicator 26a, a second indicator 26b and a third indicator 26c.

FIG. 2 illustrates in a functional manner how the various components of the present invention interact. Box 30 represents the growing medium 12 (water and soil combination). Indicators 26a, 26b, 26c and circuitry 22 are depicted in box 32 as being associated with the water and soil. Box 34 performs the test of whether the resistance from the sensors is greater than a threshold R1 to illuminate or light the indicator or dry (blue) LED 26a in box 35 when it is. Box 36 asks whether the resistance sensed is less than a second threshold R2 indicating that the soil has too much moisture and, if so, illuminating or lighting the wet LED 26b in box 37. The sensors and circuitry of box 32 are powered by a power supply 24 in box 38, whose voltage V is monitored in box 39. Box 40 tests whether the voltage V is less than a threshold voltage V1 and, when it is, box 41 drives a flasher (intermittent energization) in box 41 to illuminate or light a low power LED 26c (red in the present embodiment) in box 42.

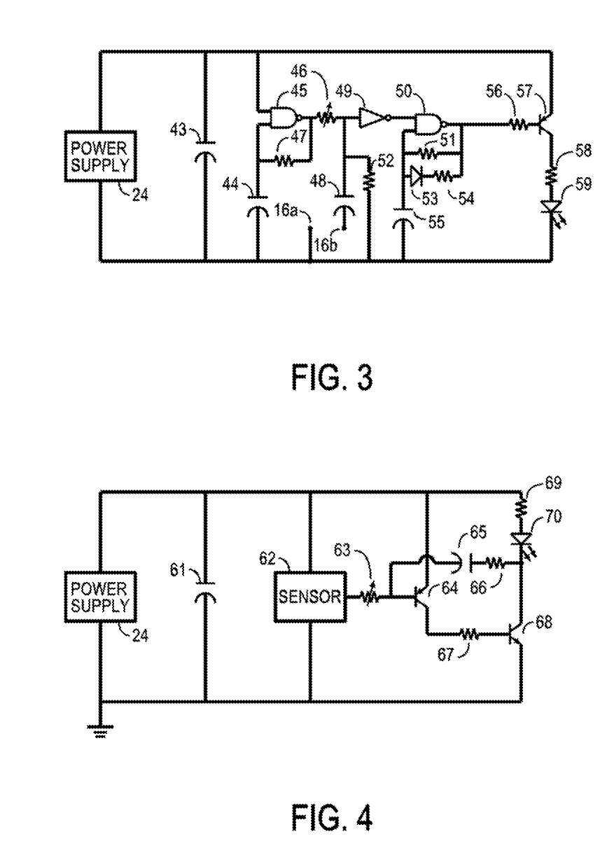

FIG. 3 illustrates one circuit for determining the resistance of the sensors 16a, 16b by measuring the resistance across them and comparing to a resistance level set by variable resistor 46 and displaying a signal through LED 59 when the relationship is met—and whether it is a “less than” or “greater than” relationship that is desired can be achieved by suitable modification of the circuit in a manner well known to those of ordinary skill in the art of circuit and logic design.

FIG. 4 is a typical circuit which is used to sense (and provide a visual indication of) the imminent failure of the power supply 24 to alert an operator that a change to the power supply would be desirable. While various indicators of the imminent failure of a power supply are known, one of the simpler methods is to periodically monitor the voltage and indicate when the voltage is below a threshold. For a battery of a nominal 3 volts, when the voltage is less than 2.4 volts, the battery is weakened and it is desirable to provide a signal (powered by that power supply) from the power supply before it fails. It is also desirable to provide a signal which requires a limited amount of power, since the indicator is that the power supply has a reduced amount of power available, and this may be achieved by intermittent powering of the indicator (flashing) and/or intermittent sensing of the power of the battery (periodic sampling, rather than continuous sampling). In this view a sensor 62 for a predetermined voltage is placed across the power supply 24. Its energization drives LED 70 with a periodic energization determined by an “RC” time constant, through transistors 64, 68. The threshold of the sensing and the period of the energization are matters of design choice—since one may wish a rapid flashing and another designer may opt for a slow flashing; one designer may want to know when the voltage of the power supply has decreased 20 percent and another designed uses a decrease of one quarter.

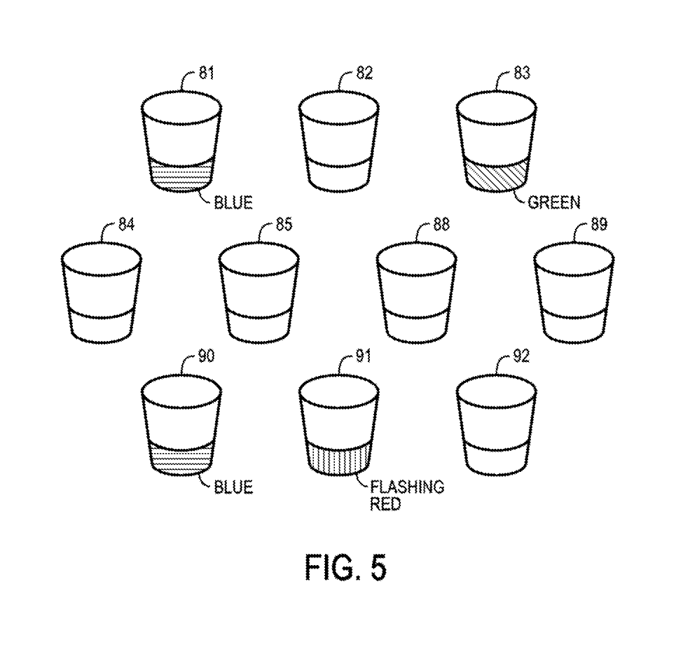

FIG. 5 illustrates a collection of pots with plants contained therein in a typical array as might be seen in a portion of a nursery or a retail establishment. The pots depicted in this view are denoted by the reference numerals 81, 82, 83, 84, 85, 86, 87, 88 89, 90, 91 and 92, although any number of such pots can be used (and in any size or combination of sizes). As shown in this view, pots 81 and 90 are glowing blue from the energization of the blue LED to indicate that the growing medium in each such pot is too dry or arid (and that watering is required). Pot 83 is glowing green to indicate that the growing media in it is too moist and steps should be taken to reduce the moisture content in it (by, at least, not watering this pot until the indicating LED is no longer lit). Pot 91 has its red LED flashing to indicate that the power supply (or battery) is weak and needs replacing.

The selection of a particular color to associate with a particular condition is a matter of design choice and ease of recollection (such as some association between the color and the condition). Red is sometimes thought to indicate danger, and a low battery is a danger to not provide power when it is needed. Green is associated with growing, and the green light could indicate that the soil is wet to grow plants. Blue is sometimes considered a symbol of dryness or heat. However, any color which is understood by the user to have a particular significant could be used to advantage in the present invention, and the flashing of a symbol could be used, if desired, to conserve power by reducing the duty cycle and increasing he chance that it would be noticed.

Of course, many modifications to the preferred embodiment can be made without departing from the spirit of the present invention. For example, the use of a translucent outer pot has been disclosed as the preferred embodiment. A transparent outer pot could be used to advantage in some applications, as can an outer pot with a transparent or translucent window covering only a portion of the wall portion of the pot. The material for the translucent pot has been disclosed as plastic in its preferred embodiment, although other translucent materials and/or different plastic materials could be used to advantage, if desired. It is also possible to mount indicators extending through a side wall of the pot so as to avoid requiring a transparent or translucent portion of the pot.

The present invention has been described in connection with a self-contained power supply in each pot, whereas some growing environments would allow for a central power supply to be used for a plurality of pots. Each pot requires power for the sensors, but that power could be supplied through wiring outside the pot if it can be provided at a low cost. In the case where power is supplied from a source which powers multiple pots, each pot would not require a power monitor unless one wishes to monitor that the power from the central source is, in fact, reaching each separate pot (insuring that the connection of a pot into the central power has been maintained).

The visual display of one or more growing conditions within a pot has been described in connection with the moisture content of the pot. However, other growing conditions such as temperature, acidity (pH) and/or fertilizer content could also be monitored if such other conditions are important to the growth of the growing medium, either alone or in combination with the moisture content. Such changes may require corresponding changes in the sensors, for instance, because the temperature may be better monitored with a thermistor, rather than a resistance-measuring circuit, but the concept is similar in providing a threshold and a signal indicating whether the measured quantity is outside of the threshold.

Those skilled in the art will realize that the sensing of the resistance of soil may be influenced by factors other than the moisture content of the soil. For one example, different soils may have different characteristics depending on the consistency of the soil, the amount of compaction and the presence of metals and other fertilizers. As another example, watering with tap water is believed to be easier to sense than watering with distilled or de-ionized water, so it is assumed that the user will be instructed as to what materials to use for optimum results. Of course, it may be possible to compensate for the use of other materials, either by knowing the effect such materials will have or by providing some kind of start up (for example, compressed soil may be watered or broken up to provide the desired level of compaction. An adjustment might be made for use of soil with a different acidity levels (pH) than the soil specified to compensate for any different in the resistance of the soil caused by the change in acidity level (pH). The resistance may also be a function of the distance separating the electrodes, so it would be desirable to position the electrodes in approximately the same separation and with generally parallel orientation for optimum results; if this is not possible, then the threshold limits must be adjusted for variations in the electrode spacing or orientation.

Further, some features of the present invention may be used without the corresponding use of other features. The power supply indicator could be replaced with a periodic test of the circuitry or by an indicator which is sensed once a day that there is enough power available to light the LEDs. In some cases, a user may be willing to assume that the power exists without separately monitoring it, especially in those circumstances where new batteries have been installed or the power comes from a central system which has been determined to be reliable in its presence and in its delivery.

As a further alternative, the sensing and/or indicators of the present invention could be sealed in a separate pouch or bag to keep the soil and moisture from the circuitry and power supply, allowing the present invention to be contained in a single pot, particularly if a display of the indicators less than all around is accommodated, as by orienting all of the pots toward an observation station and locating the indicators facing the observation station.

Accordingly, it will be appreciated that the foregoing description of the preferred embodiment is illustrative of the principles of the present invention and not in limitation thereof, as the scope of the invention is defined by the claims which follow.

Having thus described the invention, what is claimed is:

1. An apparatus for growing a plant comprising: a first container for containing the plant and a growing medium; a second container which allows light to pass therethrough adjacent the first container; a sensor within the first container and coupled to a power supply, the sensor sensing at least one condition of at least one of the plant and the growing medium; a first circuit having a first threshold coupled to the sensor, a second sensor coupled to the sensor and having a second threshold; a third sensor coupled to at least one of the sensor and the power supply and having a third threshold; and first, second and third indicators coupled to the first, second and third sensors, respectively.

2. The apparatus of claim 1 wherein at least one of the first, second and third indicators is a flashing light.

3. The apparatus of claim 1 wherein at least one of the first, second and third indicators is a colored LED.

4. The apparatus of claim 1 wherein at least one of the first, second and third indicators is a colored LED which is positioned to display a colored indication throughout the periphery of the container.

5. The apparatus of claim 1 wherein the power supply is in the second container and signals from the sensor pass through the first container into the second container through a connection which is sealed to deter water and growing medium from entering the second container.

6. An apparatus for growing a plant comprising: a container containing a growing medium and a plant with at least one portion of the container allowing light to pass therethrough; a sensor for sensing the growing conditions of the growing medium and a display positioned within the container and adjacent the light passing portion, said display having at least one indicator coupled to a sensor of the growing medium and providing a visual indication through the light passing portion, said indicator indicative of the condition of the growing medium.

7. An apparatus of the type described in claim 6 wherein the container includes a translucent portion and the display includes at least one colored LED which project a colored light different through the translucent portion of the container.

8. An apparatus of the type described in claim 7 wherein the display includes a plurality of LEDs, including at least a first LED having a first color and a second LED having a second color wherein the first LED is powered on to indicate that the growing medium is too dry and the second LED is powered on to indicate that the growing medium is too moist.

9. An apparatus of the type described in claim 8 wherein the indicators include an indicator of the condition of a power supply.

10. An apparatus of the type described in claim 9 wherein the indicator of the power supply is an indicator which is engaged when the power supply is weak.

11. An apparatus of the type described in claim 6 wherein the sensor includes a circuit for flashing an indication of the sensed condition.

12. An apparatus of the type described in claim 6 wherein the apparatus includes a timer wherein the sensing of the indicator is off for long periods compared to the time it is on.

13. An apparatus of the type described in claim 6 wherein the indicator includes a variable resistor which is adjusted to set a threshold at which the indicator is powered.

14. An apparatus of the type described in claim 6 wherein the three indicators are provided including a first indicator that the growing medium is too moist, a second indicator that the growing medium is too dry and a third indicator indicating the condition of the power for the indicators.

15. A method of making a container for sensing and indicating the conditions of a growing medium comprising the steps of: providing a container for the growing medium;
locating a first sensor within the growing medium; periodically sensing the condition of the growing medium by measuring the resistance between two contacts and determining the growing conditions as a result; powering an indicator if the growing conditions are outside a limit; and sensing the power and having an indicator of the power.

16. The method of claim 15 wherein the step of powering an indicator further includes the step of providing a colored glow through a light transmitting portion of the container.

17. The method of claim 14 wherein the step of powering an indicator includes the step of providing two different colored indicators and powering one colored indicator when a first condition is sensed and powering a second indicator having a different color when a second condition is sensed.

18. A method of claim 15 wherein the step of powering an indicator further includes the step of monitoring the power of a power supply and providing an indication of the condition of that power supply.

19. A method including the steps of claim 18 wherein the step of monitoring the power supply includes the step of providing a flashing indication of one condition of the power supply.
